(19) United States
(12) Patent Application Publication
(10) Pub. No.: US 2008/0083947 A1
(43) Pub. Date: Apr. 10, 2008

(54) SEMICONDUCTOR DEVICE AND METHOD OF FABRICATING THE SAME

(75) Inventor: Makoto Sakuma, Kuwana (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/868,130

(22) Filed: Oct. 5, 2007

(30) Foreign Application Priority Data
Oct. 6, 2006 (JP) 2006-275372

(51) Int. Cl. H01L 29/792; H01L 21/336

(52) U.S. Cl. 257/324; 438/287; 257/E29.309; 257/E21.423

(57) ABSTRACT

A semiconductor device includes a first barrier insulating film formed on upper surfaces of impurity diffusion regions and sidewalls of gate electrodes, a first insulating film formed on the first barrier insulating film so as to bury each region between the gate electrodes, a second barrier insulating film formed continuously on a metal silicide layer and the first insulating film and having an opening with a first width between the gate electrodes adjacent to each other, a second insulating film formed on the second barrier insulating film, and a contact formed by burying a conductor in a contact hole formed so as to pass through the opening of the second barrier insulating film and extend through the second insulating, the first insulating, the first barrier insulating and the gate insulating films, reaching the impurity diffusion region, the contact hole having a second width smaller than the first width.

### CROSS-REFERENCE TO RELATED APPLICATIONS

This application is based upon and claims the benefit of priority from the prior Japanese Patent Application No. 2006-275372 filed on Oct. 6, 2006, the entire contents of which are incorporated herein by reference.

### BACKGROUND OF THE INVENTION

1. Field of the Invention

The present invention relates to a semiconductor device and a method of fabricating the same, and more particularly to a non-volatile memory device and a method of fabricating the same.

2. Description of the Related Art

Refining a contact diameter has become important with progress in the refinement of memory cell transistors in semiconductor devices serving as non-volatile memories such as NAND flash memories. However, it has become difficult to refine contacts by a lithography technique. Furthermore, the resistance of a silicide layer formed on a gate electrode of a memory cell transistor needs to be lowered with refinement of the memory cell transistor. A temperature set for thermal treatment to be executed after silicidation is sometimes subjected to restrictions depending upon a metal used for forming a silicide layer. In view of this problem, silicidation is sometimes carried out in a post-process.

On the other hand, a barrier insulating film is formed over an upper surface of a semiconductor substrate for convenience in the fabricating process and in view of protective performance. When a silicide layer is formed in a post-process, a barrier insulating film formed previously needs to be removed. Accordingly, it is proposed to form a barrier insulating film twice as a countermeasure. See JP-A-2006-100409.

The aforesaid proposal employs the following process, for example: a first barrier insulating film is formed over an upper surface and sidewalls of a gate electrode and a surface of impurity diffusion region. Subsequently, an insulating film is buried between gates electrodes and planarized. Subsequently, a polycrystalline silicon film formed on an upper part of each gate electrode is exposed. In this state, a film of metal for silicide is formed and caused to react to the polycrystalline silicon film. Thereafter, unreacted metal film parts are removed. Furthermore, a second barrier insulating film is formed so as to cover a whole silicide layer, whereby an interlayer insulating film is formed.

In a double barrier structure employing the above-described process, two layers of barrier film need to be etched in execution of contact etching. As a result, it becomes difficult to control the shape and size of contact. In view of this problem, for example, above-referenced JP-A-2006-100409 discloses that a contact on a diffusion layer in a cell is refined using an upper barrier film of the double barrier structure or that the upper barrier film formed around a diffusion layer contact is removed. Consequently, etching can easily be stopped at the barrier film located immediately above the contact without difficulty of passing through double barrier films when openings are simultaneously formed in the diffusion layer and the gate contact (GC).

However, formation of refined pattern accompanies difficulty although the method disclosed by JP-A-2006-100409 has an advantage in enhancement of refinement.

### BRIEF SUMMARY OF THE INVENTION

Therefore, an object of the present invention is to provide a semiconductor device which has a structure of forming a metal silicide layer on the upper part of the gate electrode and providing a double barrier insulating film and in which the double barrier insulating film can be etched easily but reliably in forming a contact and a method of fabricating the same.

In one aspect, the present invention provides a semiconductor device comprising a semiconductor substrate having a first upper surface and a surface layer, a plurality of transistors, each of which includes a gate electrode formed on the first upper surface of the semiconductor substrate via a gate insulating film and having a second upper surface and sidewalls, a metal silicide layer formed on the second upper surface and having a third upper surface, and a plurality of impurity diffusion regions formed in the surface layer of the semiconductor substrate so as to be located at both sides of the gate electrode respectively, a first barrier insulating film formed on the first upper surface located in the impurity diffusion region and on the sidewall of the gate electrode, the first barrier insulating film having a fourth upper surface, a first insulating film formed on the fourth upper surface so as to fill a space between the gate electrodes of the transistors adjacent to each other, the first insulating film having a fifth upper surface, a second barrier insulating film formed continuously on the third and fifth upper surfaces and having an opening formed between the gate electrodes of the transistors adjacent to each other, the opening having a first width, the second barrier insulating film having a sixth upper surface, a second insulating film formed on the sixth upper surface, and a contact plug penetrating from the sixth upper surface to the one of the impurity diffusion regions through the second insulating film, the opening of the second barrier film, the first insulating film, the first barrier insulating film and the gate insulating film, the contact plug having a second width smaller than the first width.

In another aspect, the invention provides a method of fabricating a semiconductor device, comprising forming an impurity diffusion region in a semiconductor substrate so that the impurity diffusion region is located at both sides of each of gate electrodes formed on a principal surface of the substrate, forming a first barrier insulating film on sidewalls of each gate electrode of the selective gate transistor, forming a first insulating layer on the first barrier insulating film so that the first insulating layer is buried in a space between the gate electrodes, forming a metal silicide layer on the gate electrode, forming a second barrier insulating film on the metal silicide layer and the first insulating layer, forming an opening in a part of the second barrier insulating film located between the gate electrodes, the opening having a first width, forming a second insulating film on the second barrier insulating film, forming a mask layer on the second insulating film, forming an opening pattern in the mask layer located over the opening of the second barrier insulating film, the opening pattern having a second width smaller than the first width, executing an etching process with the mask layer serving as a mask so that a contact hole is formed having such a depth that the contact hole extends through the second insulating film, the opening of the second barrier insulating film, the first insulating film and the first barrier insulating film, reaching the impurity diffusion layer, and burying an electrically conductive layer in the contact hole, thereby forming a contact.

### BRIEF DESCRIPTION OF THE DRAWINGS

Other objects, features and advantages of the present invention will become clear upon reviewing the following description of the preferred embodiment with reference to the accompanying drawings in which:

FIG. 1 is an equivalent circuit diagram showing a part of memory cell array of a NAND flash memory in accordance with a first embodiment of the present invention;

FIG. 2 is a plan view showing a layout pattern of part of a memory cell region;

FIG. 3 is a sectional view taken along line 3-3 in FIG. 2;

FIGS. 4 to 16 are typical longitudinally sectional views of the memory in steps of the fabricating process (Nos. 1 to 13);

FIG. 17 is a view similar to FIG. 3, showing a second embodiment of the invention; and

FIGS. 18 to 24 are typical longitudinally sectional views of the memory in steps of the fabricating process (Nos. 1 to 7).

### DETAILED DESCRIPTION OF THE INVENTION

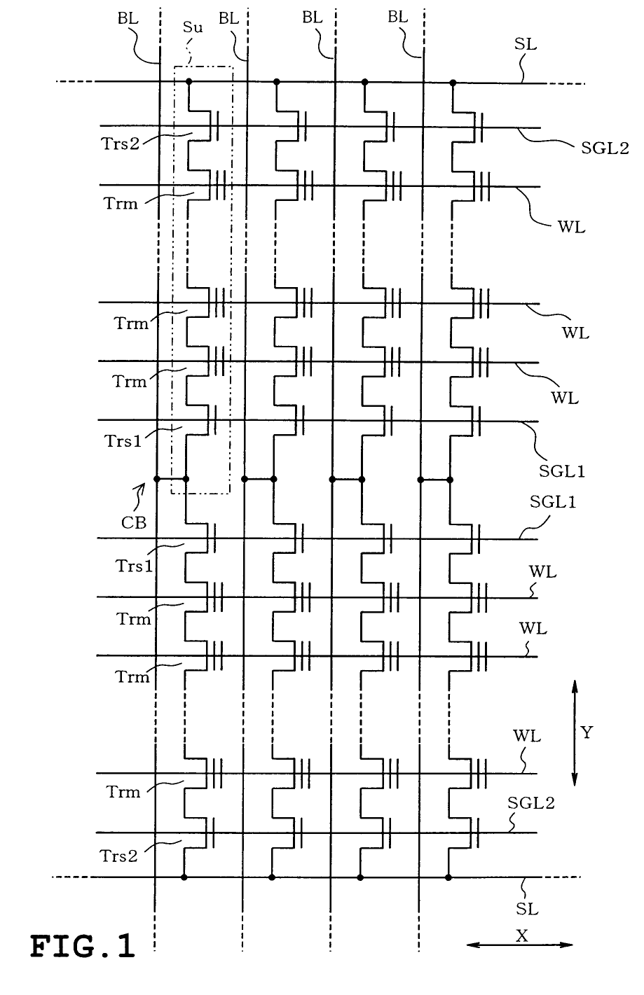

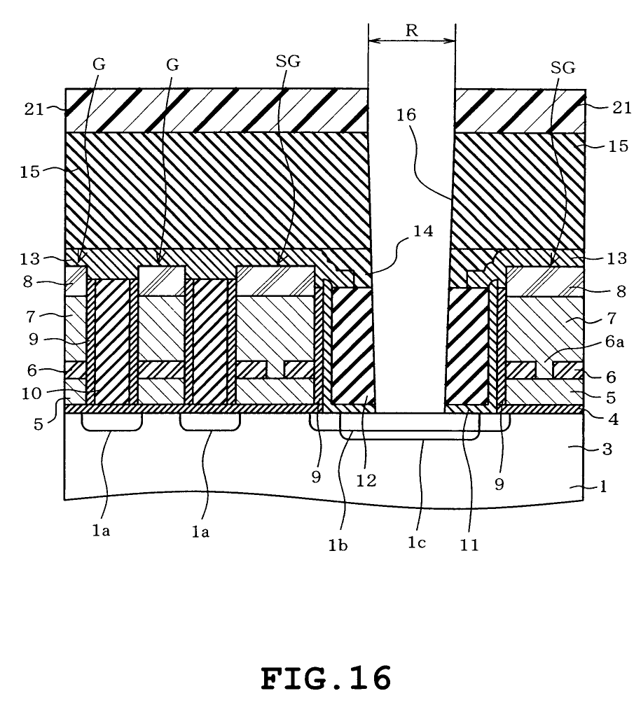

A first embodiment of the present invention will be described with reference to FIGS. 1 to 16. The invention is applied to a NAND flash memory in the embodiment. Identical or similar parts are labeled by the same reference symbols throughout figures.

Firstly, the configuration of the memory will be described. Referring to FIG. 1, a part of memory cell array of the NAND flash memory is shown as an equivalent circuit. The memory cell array a large number of NAND cell units SU formed in a matrix. Each NAND cell unit comprises two selective gate transistors Trs and a plurality of memory cell transistors Trm (2ⁿ where n is a positive number, for example, 8) series connected between the selective gate transistors Trs. In each NAND cell unit, memory cell transistors Trm adjacent to each other have a common source/drain region.

The memory cell transistors Trm arranged in the X direction (corresponding to a word line direction and gate width direction) are connected in common to a word line WL (control gate line). Furthermore, the selective gate transistors Trs1 arranged in the X direction in FIG. 1 are connected in common to a selective gate line SGL1. The selective gate transistors Trs2 are connected in common to a selective gate line SGL2. A bit line contact CB is connected to a drain region of the selective gate transistor Trs1. The bit line contact CB is connected to a bit line BL extending in the Y direction (corresponding to the direction of gate length and bit line direction) perpendicular to the X direction in FIG. 1. The selective gate transistor Trs2 is connected via a source region to a source line SL extending in the X direction in FIG. 1.

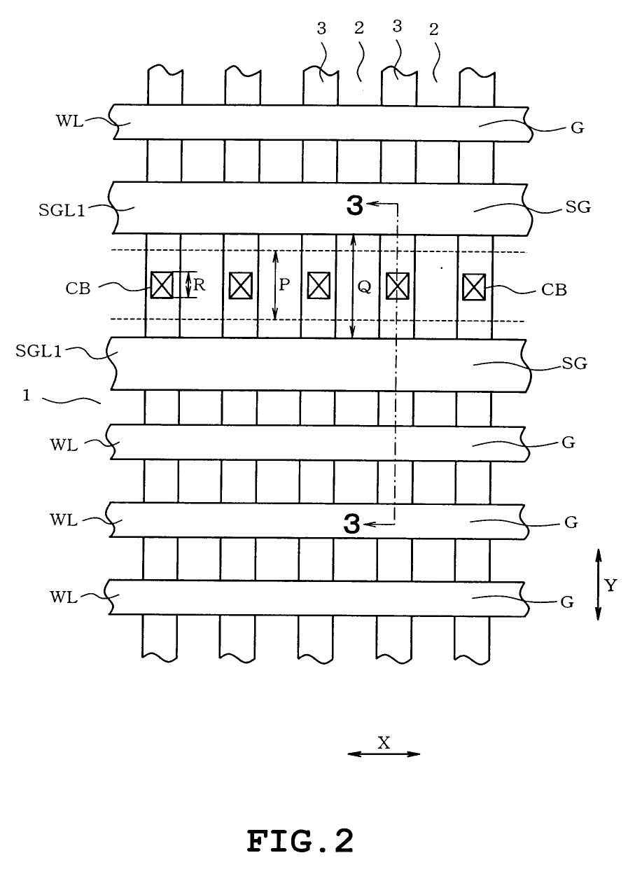

Referring now to FIG. 2, a part of memory cell region is shown. A plurality of shallow trench isolation (STI) structures 2 serving as element isolation regions are formed at predetermined intervals so as to extend in the Y direction in FIG. 2, whereby a plurality of active regions 3 are separately formed so as to extend in the X direction in FIG. 2. Word lines WL of the memory cell transistors are formed at predetermined intervals so as to extend in the X direction perpendicular to the Y direction in FIG. 2. A pair of selective gate lines SGL1 of a selective gate transistor are formed so as to extend in the X direction in FIG. 2. The active regions 3 located between the paired selective gate lines SGL1 are formed with bit line contacts CB respectively. Parts of the active regions 3 intersecting with the word lines WL are formed with gate electrodes G respectively. Parts of the active regions 3 intersecting with the selective gate lines SGL1 are formed with gate electrodes SG of the selective gate transistors respectively.

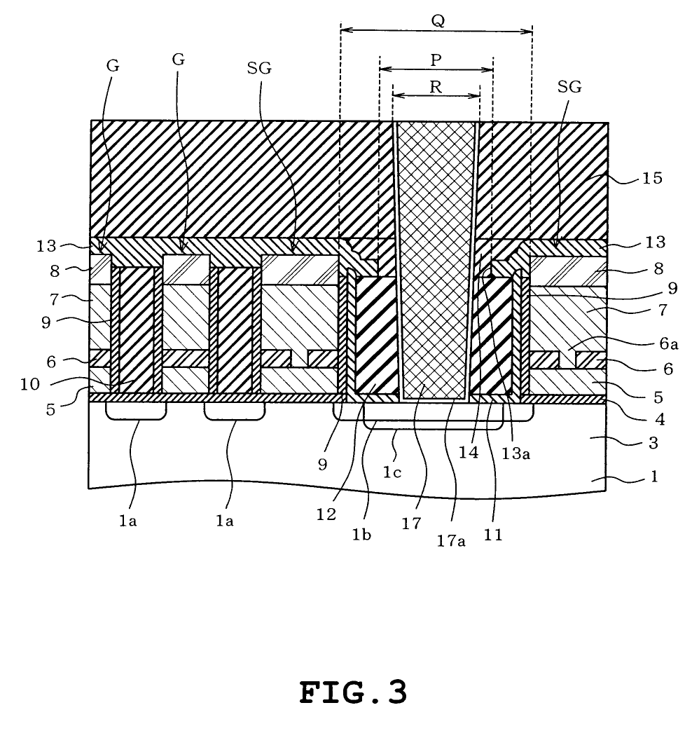

Referring now to FIG. 3, the gate electrode SG in the active region 3 is shown. The gate electrodes G and SG are formed on the semiconductor substrate 1 with a tunnel insulating film 4 being interposed therebetween. On the tunnel insulating film 4 are sequentially deposited a polycrystalline silicon film 5 for a floating gate electrode, an inter-electrode insulating film 6 comprised of an oxide-nitride-oxide (ONO) film, a polycrystalline silicon film 7 for a control gate electrode and a cobalt silicide (CoSi₂) film 8.

The inter-electrode insulating film 6 of each gate electrode SG has an opening 6a formed for rendering the polycrystalline silicon films 5 and 7 electrically conductive. The polycrystalline silicon film 7 is buried in each opening 6a. Impurity diffusion regions 1a serving as source/drain regions are formed between gate electrodes G and G and the gate electrodes G and SG. An impurity diffusion region 1b and an impurity diffusion region 1c for lightly doped drain (LDD) are formed between the gate electrodes SG and SG. Silicon oxide films 9 are formed on sidewalls of the gate electrodes G and SG by a rapid thermal processor (RTP) process so as to extend by a predetermined height from the surface of the silicon substrate 1, thereby covering two thirds of each sidewall of the polycrystalline silicon film 7. A silicon nitride film 11 serving as a first barrier insulating film is formed over the inside of the silicon oxide film 9 and the upper surface of the silicon substrate 1 between the paired gate electrodes SG. A silicon oxide film 12, such as a boro phosph silicate glass (BPSG) film, serving as a first insulating film so as to fill the inside of the silicon nitride film 11.

A silicon nitride film 13 serving as a second barrier insulating film is formed so as to cover an upper surface of the above-described structure. The silicon nitride film 13 has an upper surface which is located higher than the upper surfaces of the cobalt silicide films 8 in a region where the gate electrodes G and SG, a region between the gate electrodes G and a region between the gate electrodes G and SG. The silicon nitride film 13 has a part of an upper surface located on the silicon oxide film 12 between the gate electrodes SG. The part of the upper surface of the silicon nitride film 13 is formed so as to be located lower than the upper surface of the cobalt silicide film 8. A TEOS film 14 serving as the second insulating film is buried in this part. Furthermore, a TEOS film 15 is formed on the TEOS film 14 and planarized. Additionally, this part of the silicon nitride film 13 is formed with an opening 13a for formation of a contact. The opening 13a has a width P (a first width) which is slightly smaller than a width between the gate electrodes SG.

A contact hole 16 is formed in a region of the silicon oxide film 12 between the gate electrodes SG so as to extend from the TEOS film 15 to the surface of the silicon substrate 1. More specifically, the contact hole 16 is formed through the TEOS films 15 and 14, the silicon nitride film 13, the silicon oxide film 12 and the silicon nitride film 11 such that the surface of the silicon substrate 1 is exposed. The contact hole 16 has a width R (a second width) smaller than the width P of the opening 13a of the silicon nitride film 13. A contact plug 17 is formed in the contact hole 16 by burying a conductor therein so as to be electrically connected to the silicon substrate 1.

The above-described flash memory employs the configuration that the opening 13a having the larger first width is previously formed in the second barrier insulating film 13. Accordingly, when the contact hole 16 having the second width R smaller than the width P is formed, a step of etching the second barrier insulating film 13 is not necessitated and the fabricating process can therefore be simplified. Consequently, the contact 17 can reliably be formed by preventing failure in penetration.

The above-described flash memory is configured so that the silicon nitride film 11 serving as the first barrier insulating film is prevented form entering the region between the gate electrodes G or G and SG. Consequently, a coupling capacitance between the cell transistors can be prevented from being increased. Furthermore, the first barrier insulating film serves as a barrier against diffusion of ions, water content or the like contained in the first or second insulating film 12 or 15 or reaction between a substance of the insulating layer 12 or 15 and a cobalt-silicide 8. Additionally, the barrier films 11 and 13 also serve as stoppers when the contact hole 16 is formed.

The memory cell transistors Trm adjacent to each other in the direction of bit line commonly have the impurity diffusion layer 1a serving as a source/drain. Furthermore, the memory cell transistors are provided so that a current path is series connected between the selective gate transistors and selected by the selective gate transistors. In the embodiment, the other selective gate transistor to be connected to the current path of the memory cell transistor is eliminated in the figures. Additionally, the number of the series connected selective gate transistors may be plural, such as 8, 16, 32 or the like. Thus, the number of the selective gate transistors should not be limited.

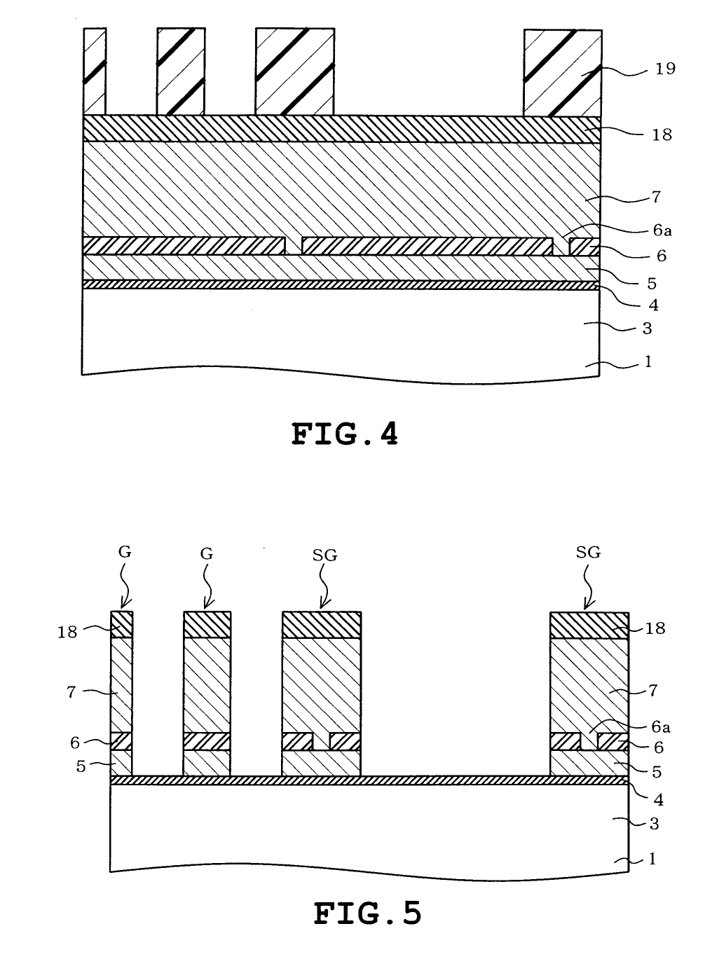

The fabrication process of the aforesaid flash memory will now be described with reference to FIGS. 4 to 16. Referring first to FIG. 4, the tunnel insulating film 4 is formed on the silicon substrate 1 and subsequently, on the tunnel insulating film 4 are sequentially deposited the polycrystalline silicon film 5 serving as a floating gate, the inter-gate insulating film 6 and the polycrystalline silicon film 7 serving as the control gate (word line). Furthermore, the silicon nitride film 18 serving as the hard mask in the dry etching process is deposited on the polycrystalline silicon film 7. Subsequently, a photolithograph process is carried out so that the resist 19 is applied to be formed into the predetermined selective gate and word line pattern. A part of the inter-gate insulating film 6 in the region where the gate electrode SG is formed is removed after the inter-gate insulating film 6 has been formed on the polycrystalline silicon film 5. When the polycrystalline silicon film 7 is formed on the inter-gate insulating film 6, the polycrystalline silicon film 7 is buried in the opening 6a.

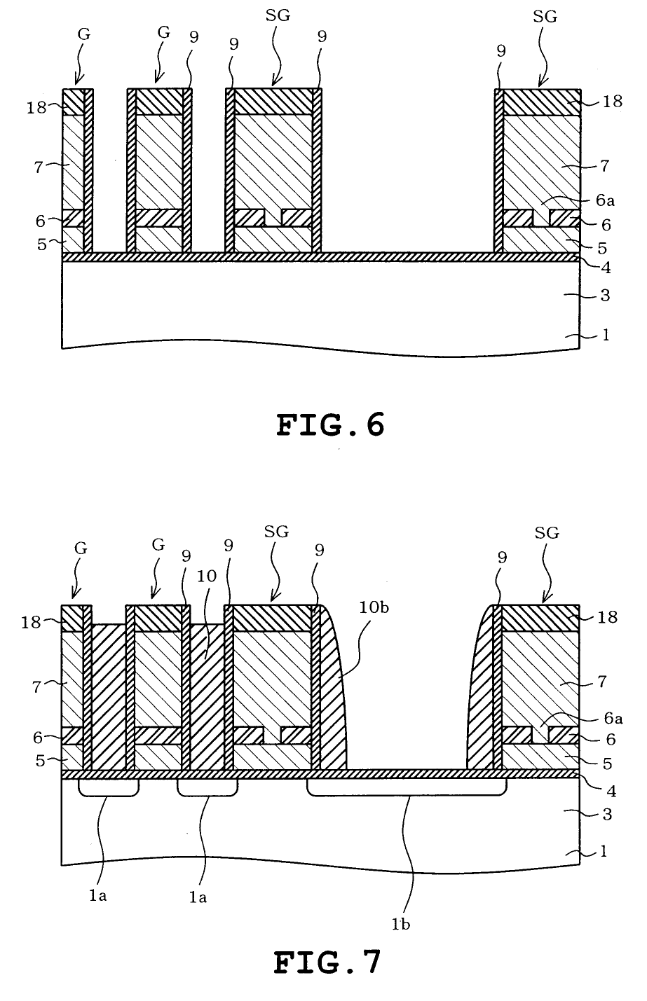

Subsequently, as shown in FIG. 5, the silicon nitride film 18 is etched by a dry etching technique (for example, a reactive ion etching (RIE) process) with the patterned resist 19 serving as the mask. Thereafter, the resist 19 is removed. Subsequently, an oxidation treatment is applied using RTP or the like. As a result, the gate electrodes G and SG, the sidewalls of the polycrystalline silicon films 5 and 7 are oxidized such that the silicon oxidized film 9 is formed as shown in FIG. 6.

Subsequently, an ion implantation process is carried out in order that impurity diffusion regions 1a and 1b may be formed as shown in FIG. 7. The impurity diffusion regions 1a and 1b correspond to a source/drain region of the memory cell transistor and the selective gate transistor. Subsequently, a low pressure chemical vapor deposition (LPCVD) is carried out so that a silicon oxide film 10 having a film thickness of about 50 nm. A dry etching process is then carried out so that the spacer 10b is formed, as shown in FIG. 7. Silicon oxide films 10 are also formed in relatively narrower spaces between the gate electrodes G and between the gate electrodes G and SG. Although the silicon oxide film 10 is etched back to a location slightly lower than the upper surface of the silicon nitride film 18 in the dry etching process, most of the silicon oxide film 10 remains. Subsequently, an ion implantation process is carried out in the region between the gate electrodes SG with the spacers 10b serving as masks, so that an impurity diffusion region 1c for the LDD structure is formed.

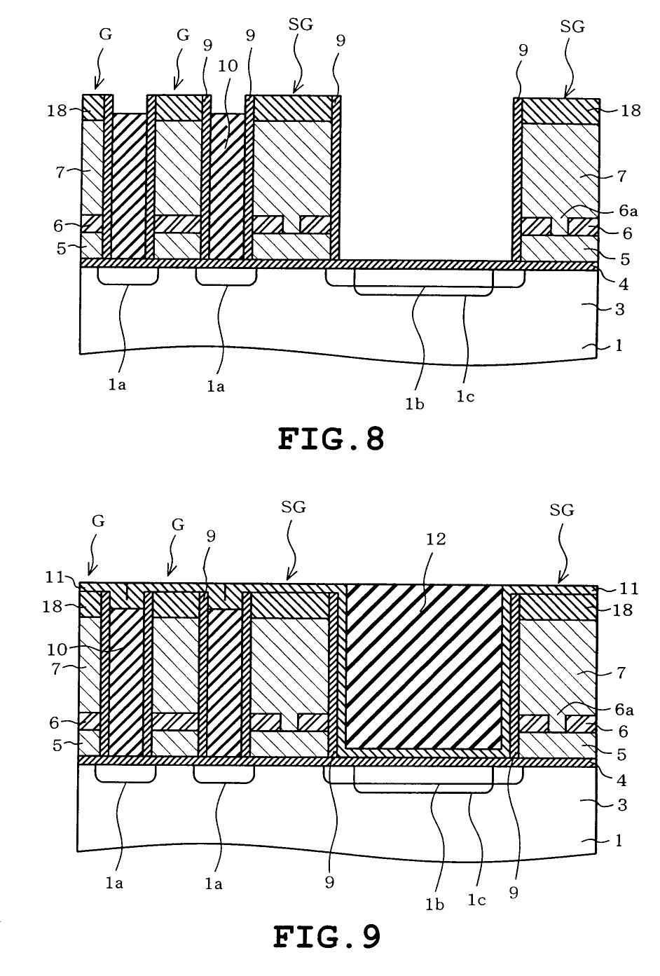

Subsequently, as shown in FIG. 8, patterning is carried out by the lithography process so that only the region between gate electrodes SG is opened, and the aforesaid spacers 10b are removed by a chemical treatment such as a fluorinated acid treatment. Subsequently, as shown in FIG. 9, the silicon nitride film 11 serving as a first barrier insulating film is formed by the LPCVD method so as to have a film thickness of about 20 nm. The silicon oxide film 12 such as a BPSG film is subsequently formed by the CVD method. Next, a melting treatment is carried out in a high-temperature wet oxidation atmosphere and a planarization treatment is subsequently carried out so that the silicon oxide film 12 is buried between the gate electrodes SG. In the planarization treatment, the silicon oxide film 12 is removed for example, by the chemical mechanical polishing (CMP) treatment with the silicon nitride film 11 serving as a stopper.

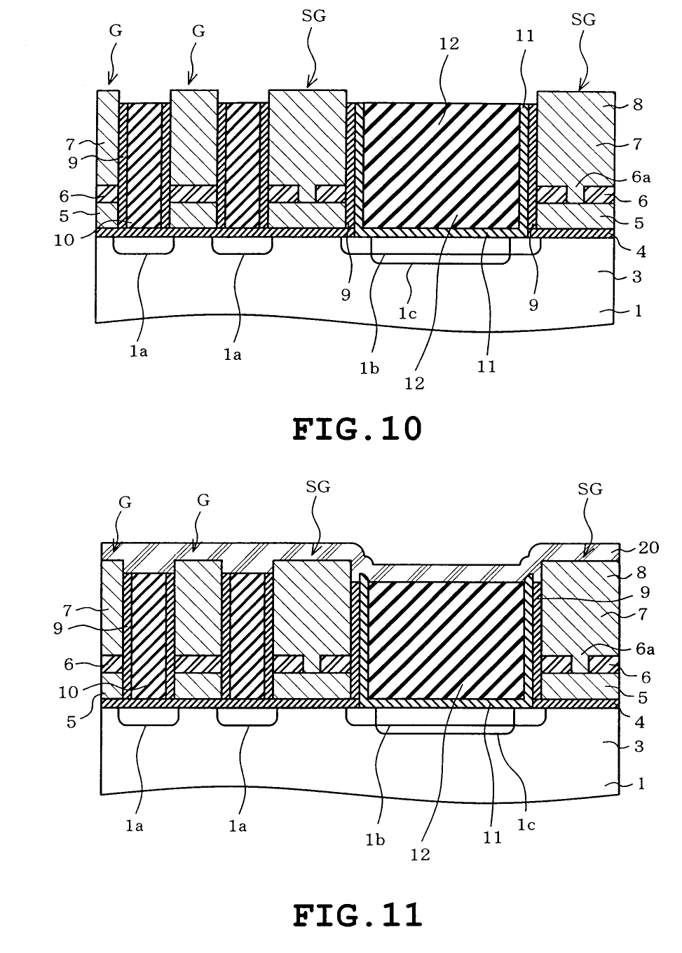

Subsequently, as shown in FIG. 10, the silicon nitride film 9 and the silicon oxide film 12 are etched by the RIE method so that an upper surface and upper portions of sides of the polycrystalline silicon films 7 of the gate electrodes G and SG are exposed. Thereafter, as shown in FIG. 11, a spontaneous oxide film or the like is removed from the exposed surface of the polycrystalline silicon film 7 to be formed into a control gate and then cleaned, and a cobalt film 20 for formation of metal silicide is formed by a sputtering technique.

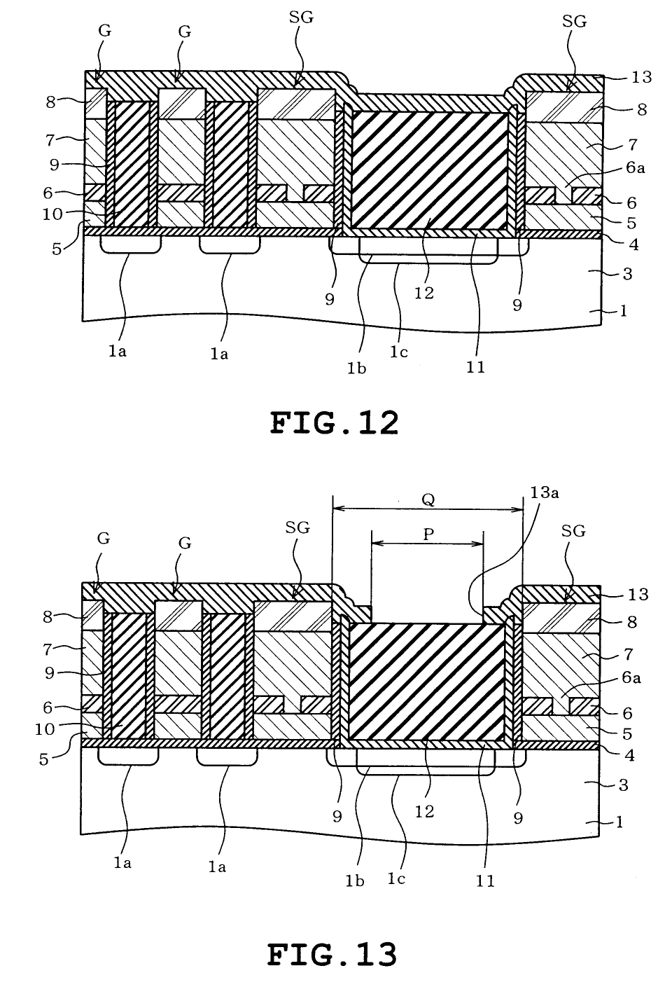

Subsequently, as shown in FIG. 12, the cobalt film 20 deposited for formation of metal silicide is annealed so that a cobalt silicide film 8 is formed. A lamp annealing technique such as RTP is employed for the annealing treatment. Only a part of the cobalt film 20 in contact with the polycrystalline silicon film 7 is silicified, and the other part of the cobalt film 20 remains unreactive. The unreactive part of the cobalt film 20 is treated by a stripping liquid thereby to be removed. Thereafter, the annealing treatment such as RTP is again carried out if needed, whereupon stable cobalt silicide (CoSi₂) film 8 is formed.

A silicon nitride film 13 with a film thickness of about 30 nm is subsequently formed as a second barrier insulating film by the LPCVD technique. The silicon nitride film 13 is formed so as to cover the cobalt silicide films 8 of the gate electrodes G and SG, the silicon oxide films 10 between the gate electrodes G and the gate electrodes G and SG and the silicon oxide film 12 between the gate electrodes SG. Subsequently, as shown in FIG. 13, a resist pattern is formed by the photolithography treatment, and a band-shaped opening 13a is formed between the gate electrodes SG of the silicon nitride film 13 so as to be connected to the gate electrodes in the direction of word line WL (in the X direction). The opening 13a has a width P smaller than a clearance between the gate electrodes SG and is formed so that an opening end thereof is located close to the gate electrodes SG.

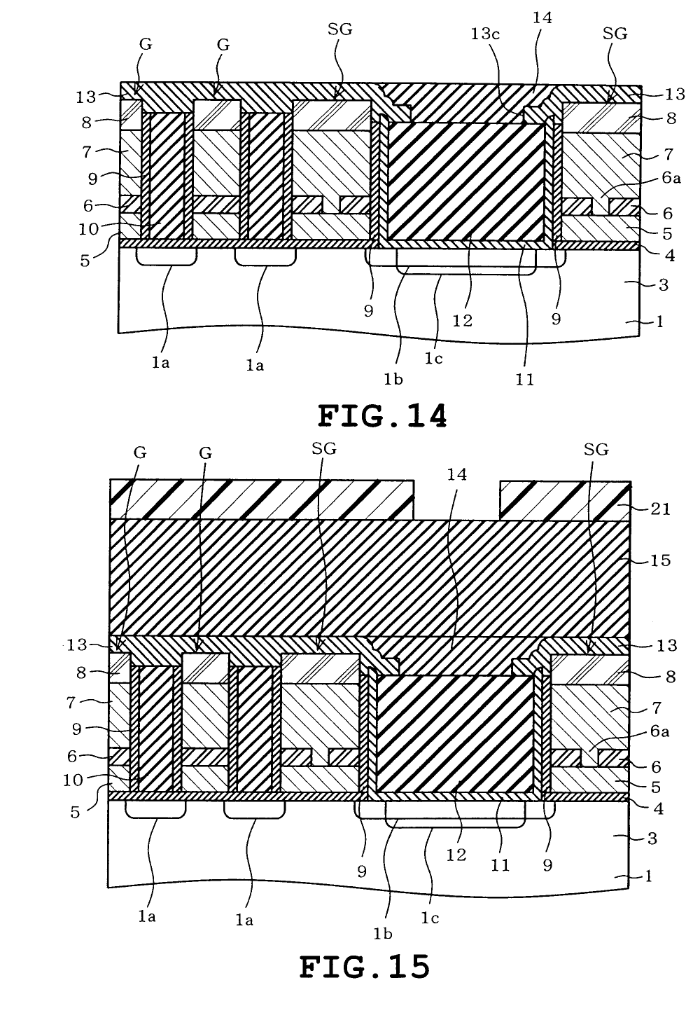

Subsequently, as shown in FIG. 14, the TEOS film 14 is formed by the LPCVD method, and the CMP treatment is carried out with the silicon nitride film 13 serving as a stopper so that the TEOS film 14 is buried in a recessed step produced in the opening 13a of the silicon nitride film 13. Subsequently, as shown in FIG. 15, a TEOS film 15 is formed by the CVD technique so as to have a film thickness of about 400 nm. A resist pattern 21 of a contact hole 16 is then formed by the photolithography treatment. The contact hole 16 is provided for forming a contact plug 17. The resist pattern 21 has an opening with a width R smaller than the width P of the opening 13a of the silicon nitride film 13.

Subsequently, a contact hole 16 is formed so as to extend through the TEOS films 15 and 14, silicon oxide film 12 and silicon nitride film 11 such that the upper surface of the silicon substrate 1 is exposed. Subsequently, as shown in FIG. 3, a conductor is buried in the contact hole 16 to be formed into a contact plug 17. More specifically, a barrier metal 17a such as TiN is formed and thereafter, the conductor is formed and buried in the contact hole 16 by the CMP treatment. Subsequently, the fabrication continues to a multilayer wiring process for the upper layer although the process is not shown.

According to the above-described embodiment, the silicon nitride film 13 serving as the second barrier insulating film is formed with the band-shaped opening 13a having the width P larger than the width R of the contact hole 16. Accordingly, in the forming of the contact hole 16, etching can reach the surface of the silicon nitride film 11 serving as the first barrier insulating film by one operation under the conditions where the silicon oxide films 15, 14 and 12 are etched. Consequently, the step of forming the contact hole 16 can be rendered easier.

Furthermore, the silicon oxide films 10 are buried in the region between the gate electrodes G, and G and SG respectively and no silicon nitride film 11 is provided. Accordingly, a parasitic capacity in the memory cell transistor can be reduced as compared with the case where the silicon nitride film 11 having a larger dielectric constant than the silicon oxide film 10. Consequently, malfunction can be prevented between the memory cells such that an electrically stable operation can be realized.

Since the first and second barrier insulating films 11 and 13 are formed in the above-described construction, impurities and moisture content can be prevented from penetrating the lower layer side and reaction can be suppressed between the cobalt silicide film 8 and the insulating film. Furthermore, the first and second barrier insulating films 11 and 13 function as stoppers in the etching or CMP treatment. Thus the barrier insulating films 11 and 13 can effectively be used in the fabrication step.

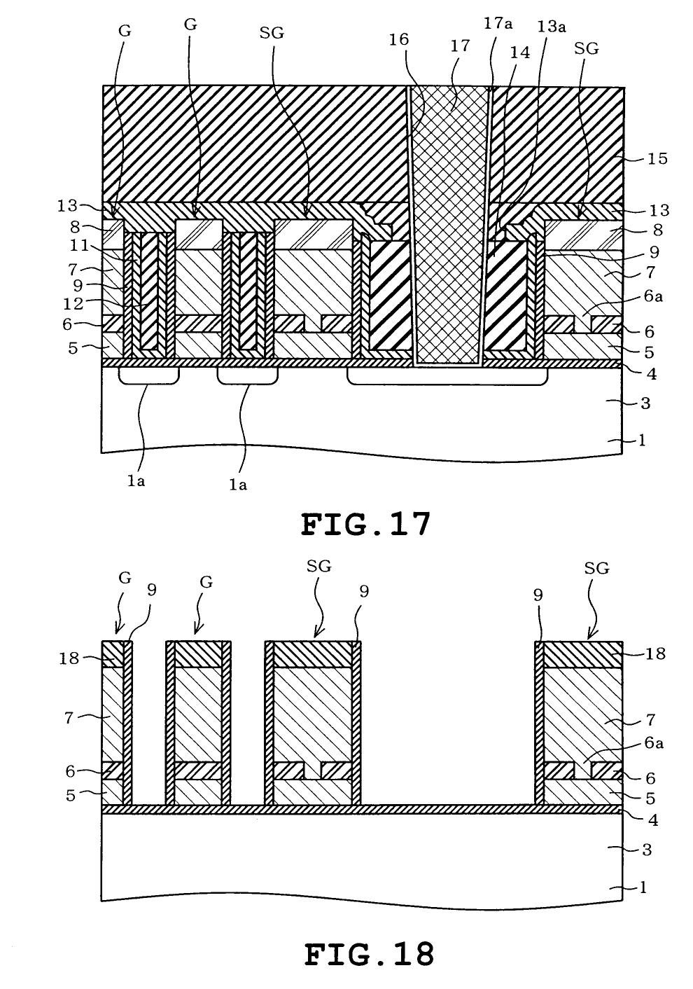

FIGS. 17 to 24 illustrate a second embodiment of the invention. The differences of the second embodiment from the first embodiment will be described. The second embodiment differs from the previous embodiment in that the silicon nitride films 11 serving as the first barrier insulating films are formed between the gate electrodes G, and G and SG. More specifically, as shown in FIG. 17, silicon oxide films 9 each formed by a thermal oxidation treatment such as RTP are provided on the sidewall of the gate electrode G and the sidewall of the gate electrode SG opposed to the aforesaid gate electrode G. The silicon nitride film 11 serving as the first barrier insulating film is formed on the surface of the silicon oxide film 9 and the upper surface of the silicon substrate 1. The silicon oxide film 12 serving as the first insulating film is formed so as to fill up the remaining void.

The above-described configuration can form the contact hole 16 by making use of the same technique as in the first embodiment. Since the silicon nitride film 11 is also formed on the sidewall of the gate electrode G, the above-described configuration can be applied the case where no electrical characteristics are influenced.

The fabrication step of the above-described configuration will be described. More specifically, only the differences in the fabrication step will be described. FIG. 18 shows the stage of the fabrication step similar to the stage in the first embodiment. More specifically, the fabrication step before the state as shown in FIG. 18 is the same as in the first embodiment.

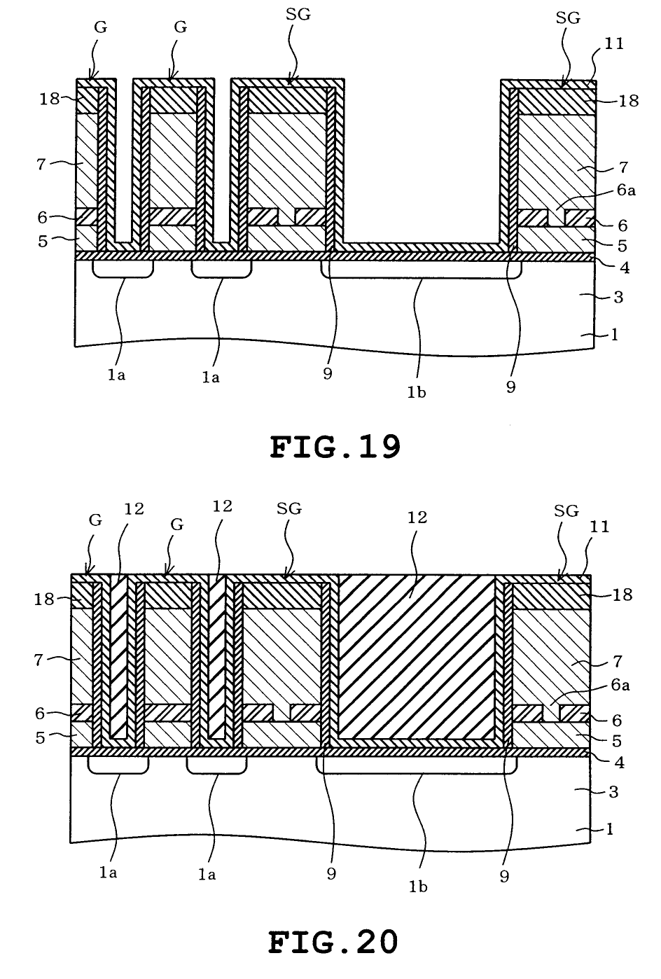

Subsequently, as shown in FIG. 19, the silicon nitride film 11 serving as the first barrier insulating film is formed by the LPCVD method so as to have a film thickness of about 20 nm. Subsequently, as shown in FIG. 20, the silicon oxide film 12 such as a BPSG film is formed by the CVD method. In this case, the silicon nitride film 11 and the silicon oxide film 12 are also formed between the gate electrodes G, and G and SG. Subsequently, a melting treatment is carried out in a high-temperature wet oxidation atmosphere and a planarization treatment is subsequently carried out so that the silicon oxide film 12 is buried between the gate electrodes SG. In the planarization treatment, the silicon oxide film 12 is removed for example, by the CMP treatment with the silicon nitride film 11 serving as a stopper.

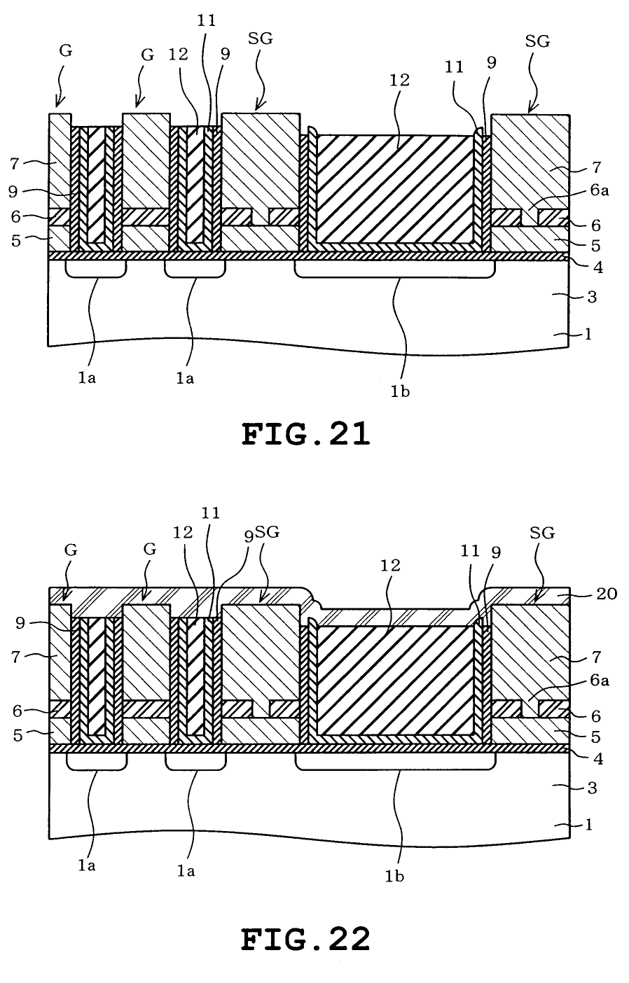

Subsequently, as shown in FIG. 21, the silicon nitride film 9 and the silicon oxide film 12 are etched by the RIE method so that an upper surface and upper portions of sides of the polycrystalline silicon films 7 of the gate electrodes G and SG are exposed. Thereafter, as shown in FIG. 22, a spontaneous oxide film or the like is removed from the exposed surface of the polycrystalline silicon film 7 and then cleaned, and the cobalt film 20 for formation of metal silicide is formed by a sputtering technique.

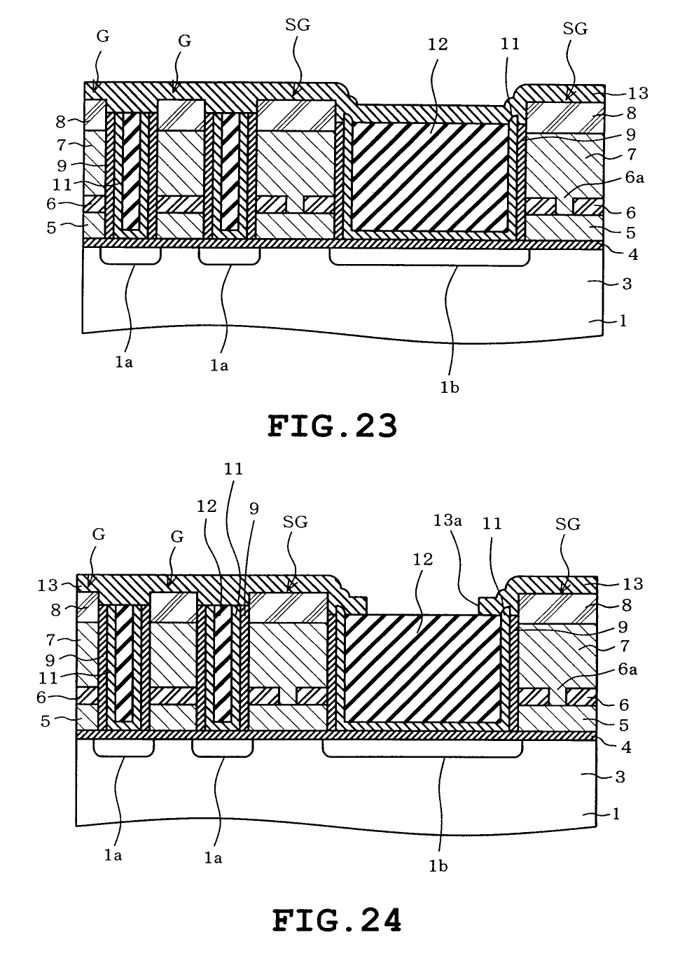

Subsequently, as shown in FIG. 23, the cobalt film 20 deposited for formation of metal silicide is annealed so that a cobalt silicide film 8 is formed. The unreactive part of the cobalt film 20 is removed. Thereafter, the annealing treatment such as RTP is again carried out if needed, whereupon stable cobalt silicide (CoSi₂) film 8 is formed. Subsequently, the silicon nitride film 13 serving as the second barrier insulating film is formed. Subsequently, as shown in FIG. 24, the band-shaped opening 13a is formed by the photolithography treatment between the gate electrodes SG of the silicon nitride film 13 so as to be connected to the gate electrodes in the direction of word line WL (in the X direction).

In the second embodiment, too, the opening 13a is formed in the silicon nitride film 13 serving as the second barrier insulating film as in the first embodiment. Consequently, the step of forming the contact hole 16 can be rendered easier. Furthermore, the second embodiment can achieve the same effect as the first embodiment regarding the first and second barrier insulating films 11 and 13.

The above-described embodiments can be modified or expanded as follows. In each embodiment, the cobalt silicide film 8 is applied to the forming of the gate electrode G of the memory cell. However, the same process can be applied to the forming of a metal silicide layer as an electrode, such as a tungsten silicide (SiW) film, nickel silicide (SiNi) film, titanium silicide film or the like.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate having a first upper surface and a surface layer;
a plurality of transistors, each of which includes:
a gate electrode formed on the first upper surface of the semiconductor substrate via a gate insulating film and having a second upper surface and sidewalls;
a metal silicide layer formed on the second upper surface and having a third upper surface; and
a plurality of impurity diffusion regions formed in the surface layer of the semiconductor substrate so as to be located at both sides of the gate electrode respectively;
a first barrier insulating film formed on the first upper surface located in the impurity diffusion region and on the sidewall of the gate electrode, the first barrier insulating film having a fourth upper surface;
a first insulating film formed on the fourth upper surface so as to fill a space between the gate electrodes of the transistors adjacent to each other, the first insulating film having a fifth upper surface;
a second barrier insulating film formed continuously on the third and fifth upper surfaces and having an opening formed between the gate electrodes of the transistors adjacent to each other, the opening having a first width, the second barrier insulating film having a sixth upper surface;
a second insulating film formed on the sixth upper surface;
and
a contact plug penetrating from the sixth upper surface to the one of the impurity diffusion regions through the second insulating film, the opening of the second barrier film, the first insulating film, the first barrier insulating film and the gate insulating film, the contact plug having a second width smaller than the first width.

2. The semiconductor device according to claim 1, wherein the first barrier insulating film comprises a silicon nitride film.

3. The semiconductor device according to claim 1, wherein the second barrier insulating film comprises a silicon nitride film.

4. The semiconductor device according to claim 1, wherein the opening is formed into a band shape so as to continuously extend across the memory cell arrays adjacent to each other.

5. A semiconductor device comprising:
a semiconductor substrate having a first upper surface and a surface layer;
a memory cell array including a predetermined number of memory cell transistors each of which is formed on the first upper surface of the semiconductor substrate via a first insulating film, each memory cell transistor having a first gate electrode;
a selective gate transistor including a second gate electrode disposed at an end of the memory cell transistors and formed on the first insulating film and a source/drain region formed in the surface layer of the semiconductor substrate, the second gate electrode having sidewalls;
a first barrier insulating film formed on the sidewalls of the second gate electrode and a surface of the source/drain region, the first barrier insulating film having a second upper surface;
a first insulating layer formed on the second upper surface so as to fill a space between the second gate electrodes of the selective gate transistors adjacent to each other, the first insulating layer having a third upper surface;
a second barrier insulating film formed continuously above the first and the second gate electrodes and the third upper surface and having a fourth upper surface, the second barrier insulating film having an opening between the second gate electrodes adjacent to each other, the opening having a first opening width smaller than a distance between the second gate electrodes adjacent to each other;
an opening formed in an upper part of the second barrier insulating film between the second gate electrodes adjacent to each other, the opening having a first opening width smaller than a distance between the second gate electrodes adjacent to each other;
a second insulating layer formed on the fourth upper surface and having a fifth upper surface; and
a contact plug penetrating from the fifth upper surface to the source/drain region through the second insulating layer, the opening of the second barrier insulating film, the first insulating layer, the first barrier insulating film and the first insulating film, the contact plug having a second width smaller than the first width.

6. The semiconductor device according to claim 5, wherein the first barrier insulating film comprises a silicon nitride film.

7. The semiconductor device according to claim 5, wherein the second barrier insulating film comprises a silicon nitride film.

8. The semiconductor device according to claim 5, wherein the first barrier insulating film is also formed on a sidewall of the gate electrode of the memory cell transistor.

9. The semiconductor device according to claim 5, further comprising a third insulating film buried in the space between the gate electrodes of the memory cell array, wherein the second barrier insulating film is formed continuously over the first and the second gate electrodes and an upper portion of the third insulating film.

10. The semiconductor device according to claim 5, wherein the opening of the second barrier insulating film is formed into a band shape so as to continuously extend over an upper surface of the gate electrode of each memory cell array and an upper part of the third barrier insulating film.

11. A method of fabricating a semiconductor device, comprising:
forming an impurity diffusion region in a semiconductor substrate so that the impurity diffusion region is located at both sides of each of gate electrodes formed on an upper surface of the substrate;
forming a first barrier insulating film on sidewalls of each gate electrode;
forming a first insulating film on the first barrier insulating film so that the first insulating film is buried in a space between the gate electrodes;
forming a metal silicide layer on the gate electrode;
forming a second barrier insulating film on the metal silicide layer and the first insulating film;
forming an opening in apart of the second barrier insulating film located between the gate electrodes, the opening having a first width;
forming a second insulating film on the second barrier insulating film;
forming a mask layer on the second insulating film;
forming an opening pattern in the mask layer located over the opening of the second barrier insulating film, the opening pattern having a second width smaller than the first width;
executing an etching process with the mask layer serving as a mask so that a contact hole is formed having such a depth that the contact hole extends through the second insulating film, the opening of the second barrier insulating film, the first insulating film and the first barrier insulating film, reaching the impurity diffusion layer; and
burying an electrically conductive layer in the contact hole, thereby forming a contact.

12. The method according to claim 11, wherein the first barrier insulating film comprises a silicon nitride film.

13. The method according to claim 11, wherein the second barrier insulating film comprises a silicon nitride film.

14. The method according to claim 11, wherein the opening of the second barrier insulating film is formed into a band shape so as to continuously extend across the memory cell arrays adjacent to each other.
